(19) United States
(12) Patent Application Publication
(10) Pub. No.: US 2013/0319518 A1
(43) Pub. Date: Dec. 5, 2013

(54) SOLAR MODULE WITH A CONNECTING ELEMENT

(71) Applicants: Matthias Doech, Muenchen (DE); Christoph Degen, Krefeld (DE); Robert Gass, Herzogenrath (DE); Thomas Happ, Muenchen (DE); Franz Karg, Muenchen (DE); Lothar Lesmeister, Landgrap (NL); Jan Boris Philipp, Muenchen (DE); Mitja Rateiczak, Wuerselen (DE); Jaap Van Der Burgt, Gorssel (NL); Andreas Schlarb, Wuppertal (DE); Bernhard Reul, Herzogenrath (DE)

(72) Inventors: Matthias Doech, Muenchen (DE); Christoph Degen, Krefeld (DE); Robert Gass, Herzogenrath (DE); Thomas Happ, Muenchen (DE); Franz Karg, Muenchen (DE); Lothar Lesmeister, Landgrap (NL); Jan Boris Philipp, Muenchen (DE); Mitja Rateiczak, Wuerselen (DE); Jaap Van Der Burgt, Gorssel (NL); Andreas Schlarb, Wuppertal (DE); Bernhard Reul, Herzogenrath (DE)

(21) Appl. No.: 13/878,174

(22) PCT Filed: Oct. 24, 2011
(86) PCT No.: PCT/EP2011/068524

§ 371 Date: Aug. 7, 2013

(30) Foreign Application Priority Data
Oct. 25, 2010 (EP) 10188687.7

(51) Int. Cl. H01L 31/0224

(52) U.S. Cl. CPC H01L 31/022441
USPC 136/256; 438/64

(57) ABSTRACT

A solar module having a connecting element is described. The solar module has a substrate, a back electrode layer, a photovoltaically active absorber layer, and a cover pane disposed one over the other, at least one prefabricated conductive film at least one connection housing.

The invention relates to a solar module with a connection element for making electrical contact. The invention further relates to a method for producing such a solar module as well as the use of the connection element.

Solar cells include, in all cases, semiconductor material. Solar cells that require carrier substrates to provide adequate mechanical strength and can be manufactured in a continuous process are referred to as “thin-film solar cells”. Due to the physical properties and the technological handling qualities, thin-film systems with amorphous, micromorphous, or polycrystalline silicon, cadmium telluride (CdTe), gallium-arsenide (GaAs), or copper indium (gallium)-sulfur/selenium (CI(G)S) are particularly suited for solar cells.

Known carrier substrates for thin-film solar cells include inorganic glass, polymers, or metal alloys and can, depending on layer thickness and material properties, be designed as rigid plates or flexible films. Due to the widely available carrier substrates and simple monolithic integration, large-area arrangements of thin-film solar cells can be produced cost-effectively.

Thin-film solar cells based on copper-indium(gallium)-sulfur/selenium (CI(G)S) have electrical efficiencies that are roughly comparable to multicrystalline silicon solar cells. CI(G)S-thin-film solar cells require a buffer layer between a typically p-conductive CI(G)S-absorber and a typically n-conductive front electrode layer, which usually contains n-doped zinc oxide (ZnO). The buffer layer can effect an electronic adaptation between the absorber material and the front electrode. The buffer layer contains, for example, a cadmium-sulfur compound.

From EP 2 200 097 A1, a method is known wherein a plurality of solar cell regions are serially connected in an integrated form by means of suitable structuring and connection of a back electrode layer, absorber material, buffer layer, and front electrode layer. Moreover, the positive and negative power connections of the solar cell composite are guided through the back electrode layer to the outer edge of the solar module and contact is made there by means of bus bars.

From DE 10 2005 025 632 A1 or DE 100 50 614 C1, it is known that the electrical contacting of the back electrode layer with external feed lines is accomplished via a spring contact element, with the spring contact guided through a through-hole and contacting the bus bar.

The object of the present invention consists in providing an improved solar module with a connection element that enables making a reliable electrical contact of the photovoltaic layer without reducing the mechanical stability of the substrate by a recess or an opening.

The object of the present invention is accomplished according to the invention by a solar module with a connection element according to claim 1. Preferred embodiments emerge from the subclaims.

A method for producing a solar module with a connection element as well as a use of the connection element emerge from other claims.

Thin-film solar cells are differentiated with regard to their layer arrangement into two configurations: In the so-called “substrate configuration”, the back electrode and the photovoltaically active absorber layer are deposited directly onto a substrate. The substrate is situated on the side of the thin-film solar cell facing away from light incidence. In the so-called “superstrate configuration”, the front electrode is deposited directly onto a cover pane. The cover pane is situated on the side of thin-film solar cell facing the light incidence.

The solar module with a connection element according to the invention preferably comprises a solar module in the substrate configuration. The substrate has a back electrode layer on the front side and the back electrode layer is partially connected electrically conductively to a photovoltaically active absorber layer.

The photovoltaically active absorber layer in the context of the invention comprises at least one p-conductive semiconductor layer and one n-conductive front electrode layer. The front electrode layer is transparent to radiation in the spectral range sensitive for the semiconductor layer. The front electrode layer is disposed on the side of the photovoltaically active absorber layer facing away from the back electrode.

The photovoltaically active absorber layer particularly preferably comprises a p-conductive semiconductor layer, at least one buffer layer, and an n-conductive front electrode layer.

The solar module with a connection element according to the invention preferably comprises a solar module in superstrate configuration. Here, a cover pane is connected on its back side via a front electrode layer to a photovoltaically active layer.

The front side of the substrate is connected by means of at least one intermediate layer to the back side of the cover pane. Since, in the substrate configuration, the front side of the substrate has, over a large surface, the back electrode layer and the photovoltaically active absorber layer, the connection between the substrate and intermediate layer is made via these layers over a large surface. Since, in the superstrate configuration, the back side of the cover pane has, over a large surface, the photovoltaically active absorber layer and the back electrode layer, the connection between the substrate and the intermediate layer is made via these layers over a large surface.

At least one foil conductor is electrically conductively connected to the back electrode layer and/or the front electrode layer. The foil conductor is disposed around the side edge of the substrate and affixed on the back side of the substrate. In an alternative embodiment of the invention, the foil conductor is disposed around the side edge of the cover pane and affixed on the front side of the cover pane. It is also possible to affix one of the foil conductors on the back side of the substrate and a second foil conductor on the front side of the cover pane. The foil conductor is preferably disposed around the side edge of the substrate and affixed on the back side of the substrate.

The foil conductor has a connection point for making electrical contact. At least one connection housing is affixed on the back side of the substrate or the front side of the cover pane. The connection housing has at least one electrical line connection between a contact element and the connection point of the foil conductor.

The cover pane and the substrate are preferably made of tempered, partially tempered, or non-tempered glass, in particular float glass. The cover pane contains, in particular toughened or non-toughened low-iron soda-lime glass with high permeability for sunlight. The cover pane and substrate preferably have thicknesses of 1.5 mm to 10 mm. The intermediate layers preferably contain thermoplastics, such as polyvinyl butyral (PVB) or ethylene vinyl acetate (EVA) or a plurality of layers thereof, preferably with thicknesses of 0.3 to 0.9 mm. The substrate and cover pane are fixedly bonded to each other via one or a plurality of intermediate layers using heat and pressure or under vacuum.

The foil conductor, sometimes also called “flexible flat conductor”or “flat-band conductor” is commonly made of a metal strip such as a tinned copper strip with a thickness of 0.03 mm to 0.3 mm and a width of 2 mm to 16 mm. Copper has proved itself for such conductor tracks, since it has good electrical conductivity as well as good processability into foils. At the same time, material costs are low. Other electrically conductive materials that can be processed into foils can also be used. Examples for this are aluminum, gold, silver, or tin and alloys thereof.

For electrical insulation and for stabilization, the foil conductor is applied on a carrier material made of plastic or laminated therewith on both sides. The insulation material contains, as a rule, a 0.025 mm to 0.1 mm thick film based on a polymer, such as polyimide, polyester, polyethylene, silicone, polyacrylic, polyurethane, polyisobutylene, polytetrafluoroethylene, ethylene vinyl acetate, polyvinyl fluoride, polyethylene naphthalate, or combinations thereof. Other plastics or materials with the required insulating properties can also be used. A plurality of conductive layers electrically isolated from each other can be situated in one foil conductor. It is understood that foil conductors insulated on one side are disposed with their non-insulated side on an electrically insulating subsurface such as a substrate or cover pane.

Such foil conductors with plastic insulation on one or both sides are easily producible industrially and can be obtained economically. The foil conductors can be already made in advance (prefabricated) and freed of the plastic insulation, for example, at the connection points. Prefabricated foil conductors can be processed easily and automatically. Preferably, a prefabricated foil conductor is used in the production of the solar module according to the invention, bringing with it process technology advantages (e.g., simple processability, safe and reliable insulation of the metal strip). As already mentioned, the foil conductor can be provided on one or both sides with plastic insulation. The term “prefabricated” or “made in advance” indicates that the foil conductor already has, before application on the solar module, a metallic strip with associated plastic insulation. The plastic insulation is thus, for example, not fixedly bonded to the metallic strip only at the time of lamination of the solar module.

Preferably, a foil conductor is used wherein a metallic strip is laminated into the plastic insulation on both sides. In this case, the foil conductor contains no adhesive layer to affix the plastic insulation on the metallic strip. The plastic insulation is made, in this case, of a thermoplastic (e.g., EVA=ethylene vinyl acetate), in other words, of a material that melts with an increasing temperature and forms, after solidification, a firm bond with the metallic strip. The term “lamination” refers to the procedure of the bonding of the metallic strip to the plastic insulation by means of a temperature increase to melt the plastic insulation and subsequent cooling to solidify the plastic insulation and to bond with the metallic strip. Preferably, for the lamination, the metallic strip is disposed in a “sandwich structure” between two layers of plastic insulation film. Optionally, in the lamination of the two, pressure is exerted on the lamination composite to strengthen the adhesive force. A foil conductor in which a metallic strip is laminated between layers of plastic insulation has the advantage of particularly high stability in the long-term use of the solar module, since, with an adhesive layer, it cannot be ruled out that the plastic insulation will become detached from the metallic strip over time. This is the case especially with solar modules that are frequently in use for several decades. It is also conceivable to use a foil conductor in which the metallic strip is laminated to a plastic insulation on only one side.

Metallic strips without plastic insulation must be adhered to a plastic layer or the like for insulation and for protection against corrosion. For this, an additional process step is necessary, resulting in additional costs. For adequate protection against corrosion, the plastic layer must protrude far beyond the foil conductor or cover the complete side of the module. This creates clearly higher material costs than with the solution according to the invention.

The foil conductor is electrically conductively connected to the back and/or front electrode layer. The connection is preferably made by welding, bonding, soldering, clamping, or gluing with an electrically conductive adhesive.

Foil conductors that are suitable for making contact of back and/or front electrode layers in solar modules have a maximum total thickness of only 0.5 mm. Such thin foil conductors can be embedded without difficulty between the substrate and the cover pane in the intermediate layer. This requires that the plastic insulation of the foil conductor be correspondingly thin.

The foil conductor has, on the back side of the substrate or the front side of the cover pane, a connection point for making electrical contact. This is preferably a through-hole in the outer plastic insulation of the foil conductor such that the metallic internal conductor of the foil conductor is freely accessible to contact elements. The connection points can already be pre-tinned, which facilitates a subsequent electrical line connection, for example, in a soldering procedure.

The foil conductor is preferably glued to the substrate or the cover pane. The adhesive serves to seal the region between the foil conductor and substrate or cover pane. The adhesive protects the interior of the thin-film solar cell from penetrating moisture.

The present invention also includes at least one single or multiple part connection housing with at least one electrical feed line and one contact element to form an electrical line connection with the connection point of the foil conductor.

The connection housing is preferably made from an electrically insulating material. Thermoplastics and elastomers that are processed by injection molding methods are appropriate for industrial production of the connection housing. Used as thermoplastics and elastomers are, for example, polyamide, polyoxymethylene, polybutylene terephthalate, or ethylene propylene diene rubber. Alternatively, hotmelt molding material such as acrylate or epoxy resin systems can also be used to produce the connection housing. The connection housing can be made of metal or of another electrically conductive material with electrically insulating inserts.

Preferably used as contact elements are contact pins or spring contact elements made of metal. For the preferred application objective in a solar module, a solder-free, clamping connection suffices since with use in buildings, the contact location is usually exposed to no vibrations. If need be, the electrical line connection between contact elements can also be welded, bonded, soldered, glued, or additionally secured.

The connection housing can serve as the base for a connection plug or a connection line. Moreover, it can accommodate further functional elements such as diodes or an electrical control system.

The connection housing is affixed on the back side of the substrate or the front side of the cover pane, preferably by gluing and is sealed. The gluing takes place preferably by means of an adhesive strand or adhesive strip with an adhesive on an acrylic, polyurethane, or polyisobutylene basis. By means of the adhesive bonding, the interior of the housing can be hermetically sealed against gases, water, or moisture. This protects the contact location in the interior of the housing against corrosion.

In a preferred embodiment of the invention, the connection point of the foil conductor is disposed in a region of the circumferential edge surface of the substrate. In this manner, a particularly flat construction of the solar module can be obtained. In a preferred embodiment of the solar module according to the invention, the foil conductor is electrically conductively connected to the back electrode layer.

In an advantageous embodiment of the solar module according to the invention, the foil conductor is connected via a bus bar to the back electrode layer and/or the front electrode layer. The bus bar can, in principle, be designed as a foil conductor or the electrically conductive layer of a foil conductor. Electrically conductive materials that can be processed into foils can be used as bus bars. The bus bar preferably contains a metal, particularly preferably aluminum, copper, gold, silver, or tin and alloys thereof. The bus bar preferably has a thickness of 0.03 mm to 0.3 mm and a width of 2 mm to 16 mm. The bus bar usually extends along the long side of a solar module that is rectangular when viewed from above.

The electrically conductive connection between the foil conductor and the bus bar is preferably situated in the center of the long direction of the bus bar. Since the bus bar itself has ohmic resistance, a voltage drop occurs when current flows through the bus bar. With an electrical contact made in the center of the long direction of the bus bar, a more homogeneous distribution of the current flow through the solar module and the bus bar is achieved than with an electrical contact at one end of the bus bar. Moreover, the maximum current density in the bus bar in the region of the power tap is less than in the case of making contact at one end. This enables the use of bus bars with a smaller cross-sectional area, for example, with a smaller width. Through the use of narrower bus bars, the photovoltaically active area of the solar module can be enlarged and the area-dependent power output increased.

In an advantageous embodiment of the solar module according to the invention, the back electrode layer contains a metal, preferably molybdenum, titanium nitrides, or tantalum nitrides. The back electrode layer can include a layer stack of different individual layers. Preferably, the layer stack contains a diffusion barrier made of silicon nitride to prevent diffusion of, for example, sodium out of the substrate into the photovoltaically active absorber layer.

In an advantageous embodiment of the solar module according to the invention, the front electrode layer contains an n-conducting semiconductor, preferably aluminum-doped zinc oxide or indium-tin oxide.

In an advantageous embodiment of the solar module according to the invention, the p-conductive semiconductor layer of the photovoltaically active absorber layer contains amorphous, micrmorphous, or polycrystalline silicon, cadmium telluride (CdTe), gallium arsenide (GaAs), or copper-indium (gallium)-sulfur/selenium (CI(G)S).

In an advantageous embodiment of the solar module according to the invention, the substrate has an undercut relative to the cover pane or is offset compared to the cover pane. The undercut, i.e., the distance between the side edges of the substrate and the cover pane, preferably amounts to 0.1 mm to 20 mm, particularly preferably 1 mm to 5 mm. The undercut can extend beyond the width of the circumferential side edge of the substrate or to only a region around the point of exit of the foil conductor. The foil conductor runs, without an overhang, around the side edge of the substrate in the region of the undercut. It does not protrude and is largely protected against damage during transport and assembly.

In an advantageous embodiment of the solar module according to the invention, the gap between the substrate and the cover pane is sealed by an edge seal, preferably by an adhesive on an acrylic, polyurethane, or polyisobutylene basis. The edge seal prevents the penetration of air, water, or moisture and protects the sensitive semiconductor layers and metal layers against corrosion. In one embodiment, the edge seal is disposed on one side of the foil conductor. It can be advantageous with regard to the penetration of air, water, and moisture for the edge seal to be disposed on both sides of the foil conductor, i.e., for the foil conductor to be disposed as a “sandwich structure” between two sections of the edge seal.

In another advantageous embodiment of the solar module according to the invention, the foil conductor has, outside the composite made of the substrate, intermediate layer, and cover pane, a protective layer, preferably a protective layer based on a polymer, such as polyimide, polyester, polyethylene, silicone, polyacrylic, polyurethane, polyisobutylene, polytetrafluoroethylene, ethylene vinyl acetate, polyvinyl fluoride, or polyethylene naphthalate, or combinations thereof. The protective layer contains, particularly preferably, a layer sequence made of polyvinyl fluoride/polyester/polyvinyl fluoride and is glued by an ethylene vinyl acetate layer to the surface of the substrate. The protective layer preferably has a thickness of 0.1 mm to 1 mm and a width of 3 mm to 50 mm. The protective layer protects the foil conductor against mechanical damage. In addition, the protective layer increases the dielectric strength to the voltage-carrying layers and reduces leakage currents. Preferably, the protective layer spans the exit point of the foil conductor between the substrate and the cover pane and is, for this purpose, bonded to the substrate and the cover pane. Alternatively, it would also be possible for the protective layer to be fixedly bonded to the connection housing instead of being affixed on the substrate or the cover pane, depending on where the connection housing is situated. The protective layer is different from the plastic insulation of the foil conductor. Additionally, the protective layer is different from the thermoplastic intermediate layer for bonding the substrate and the cover pane. By means of the protective layer, protection can be obtained, in particular, against penetration of air, water, moisture into the region of the exit point of the foil conductor. When, in the solar module according to the invention, the substrate has an undercut relative to the cover pane, it can also be advantageous for the protective layer to be bonded to the cover pane in the region of the section of the cover pane protruding relative to the substrate, such that the protective layer does not protrude beyond the side edge of the cover pane. This measure enables realization of particularly long-lasting protection of the exit point of the foil conductor.

In another advantageous embodiment of the solar module according to the invention, the interior of the connection housing is sealed by a sealing means, preferably by an adhesive on an acrylic, polyurethane, or polyisobutylene basis. The sealing means prevents the penetration of air, water, or moisture into the interior of the connection housing and protects the electrical line connection between the foil conductor and the contact element against corrosion.

Alternatively or additionally, a protective element that protects the foil conductor against mechanical damage can be applied on the connection housing. The protective element can, for example, contain a plastic. The protective element can preferably be disposed in the region of the side edge of the substrate. Preferably, the protective element does not protrude beyond the side edge of the cover pane. The intermediate space between the protective element and substrate or cover pane preferably has a sealing material, for example, an adhesive on an acrylic, polyurethane, polyisobutylene, or silicone basis. By means of the sealing material, the dielectric strength to voltage-carrying layers, such as the electrically conductive layer of the foil conductor, is increased. At the same time, leakage currents, for example, due to penetrating moisture, are reduced.

In an advantageous embodiment of the solar module according to the invention, the electrical line connections between the foil conductor and the back and/or front electrode layer, between the bus bar and the back and/or front electrode layer, between the foil conductor and the bus bar and/or between the foil conductor and the contact element have soldered, welded, bonded, or clamped connections. The electrical line connections can also have adhesive connections with an electrically conductive adhesive.

In an advantageous embodiment of the solar module according to the invention, the solar module has two foil conductors and two connection housings. One foil conductor is preferably connected to the positive power connection of the solar module; the second foil conductor, to the negative power connection of the solar module.

In an advantageous embodiment of the solar module according to the invention, at least two foil conductors are electrically conductively connected, on the back side of the substrate or the front side of the cover pane, in a connection housing, to at least two contact elements. The two contact elements can, for example, be connected via a double-pole cable or a double-pole plug to another electrical circuit.

The invention also includes a method for producing a solar module according to the invention with a connection element. The method includes at least the following steps: In a first step, a back electrode layer is applied to the front side of a substrate. Then, at least one semiconductor layer, thereafter a buffer layer, and thereafter a front electrode layer are applied to the back electrode layer. The semiconductor layer, the buffer layer, and the front electrode layer form the photovoltaically active absorber layer. The back electrode layer and the photovoltaically active absorber layer are electrically conductively connected to each other. The back electrode layer, the semiconductor layer, the buffer layer, and the front electrode layer are structured and connected using methods known per se for producing an integrated serial circuit of individual solar cells into a solar cell module. In a second step, a preferably prefabricated or ready-made foil conductor is electrically conductively connected to the back electrode layer and/or front electrode layer. The electrically conductive connection is made, for example, by welding, bonding, soldering, clamping, or gluing with an electrically conductive adhesive. In a third step, the substrate and the cover pane are bonded to each other by means of an intermediate layer under the action of heat, vacuum, and/or pressure. In a fourth step, the foil conductor is placed around the side edge of the substrate and is affixed on the back side of the substrate, for example, by gluing or clamping. After that, a connection housing with at least one contact element is affixed on the back side of the substrate, for example, by gluing or clamping, and the contact element is electrically conductively connected to the connection point of the foil conductor.

The invention also includes a method for producing a solar module with a connection element according to the invention in superstrate configuration. The method includes at least the following steps: In a first step, a front electrode layer is applied on the back side of a cover pane. Then, at least one buffer layer, thereafter a semiconductor layer, and thereafter a back electrode layer are applied on the front electrode layer. The semiconductor layer, the buffer layer, and the front electrode layer form the photovoltaically active absorber layer. The back electrode layer and the photovoltaically active absorber layer are electrically conductively connected to each other. The back electrode layer, the semiconductor layer, the buffer layer, and the front electrode layer are structured and connected using methods known per se for producing an integrated serial circuit of individual solar cells into a solar module. In a second step, a preferably prefabricated or ready-made foil conductor is electrically conductively connected to the back and/or front electrode layer. The electrically conductive connection is made, for example, by welding, bonding, soldering, clamping, or gluing with an electrically conductive adhesive. In the third step, the substrate and the cover pane are bonded to each other by means of an intermediate layer under the action of heat, vacuum, and/or pressure. In a fourth step, the foil conductor is placed around the side edge of the substrate and affixed on the back side of the substrate, for example, by gluing or clamping. After that, a connection housing with at least one contact element is affixed on the back side of the substrate, for example, by gluing or clamping, and the contact element is electrically conductively connected to the connection point of the foil conductor.

In an alternative embodiment of the method according to the invention, the preferably prefabricated or ready-made foil conductor is placed in the respective respective fourth step around the side edge of the cover pane and affixed on the front side of the cover pane. After that, the connection housing is affixed on the front side of the cover pane.

For the bonding of the cover pane and substrate by means of an intermediate layer, the methods familiar to the person skilled in the art can be used with or without prior production of a pre-composite. For example, so-called autoclave methods can be performed at an elevated pressure of roughly 10 bar to 15 bar and temperatures of 130° C. to 145° C. over roughly 2 hours. Vacuum sack or vacuum ring methods known per se operate, for example, at roughly 200 mbar and 130° C. to 145° C.

Preferably, the cover pane and substrate can be pressed with an intermediate layer in a calender between at least one pair of rollers to form a solar module according to the invention. Systems of this type are known for producing composite glazings and normally have at least one heating tunnel upstream from a pressing plant. The temperature during the pressing procedure is, for example, 40 to 150° C. Combinations of calender and autoclave methods have particularly proved themselves in practice.

Alternatively, vacuum laminators are used for producing the solar modules according to the invention. These consist of one or a plurality of heatable and evacuable chambers in which the cover pane and substrate can be laminated within, for example, roughly 60 minutes at reduced pressures of 0.01 mbar to 800 mbar and temperatures of 80 ° C. to 170° C.

In another embodiment of the method according to the invention, after the first step, a bus bar is electrically connected to the back electrode layer and/or front electrode layer, for example, by welding, bonding, soldering, clamping, or gluing with an electrically conductive adhesive. In the second step, the foil conductor is electrically conductively connected to the bus bar. The foil conductor is then electrically conductively connected via the bus bar to the back electrode layer and/or front electrode layer.

The invention also includes the use of the connection element for making electrical contact of a solar module, in particular of a thin-film solar module.

In the following, the invention is explained in detail with reference to drawings. The drawings are schematic representations and not true to scale. In particular, the layer thicknesses of the foil conductor are depicted significantly enlarged by way of illustration. The drawings in no way restrict the invention.

They depict:

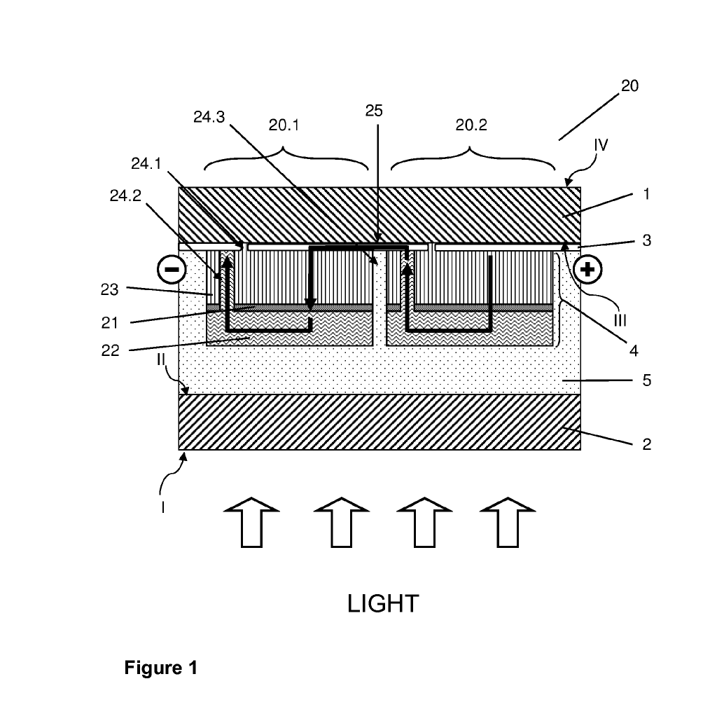

FIG. 1 a cross-sectional drawing of a solar module according to the invention with two serially connected solar cells in substrate configuration,

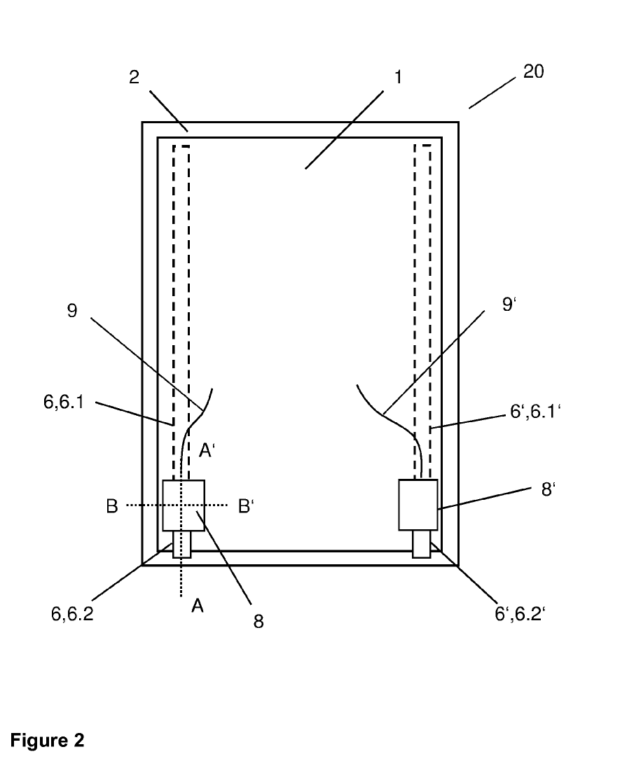

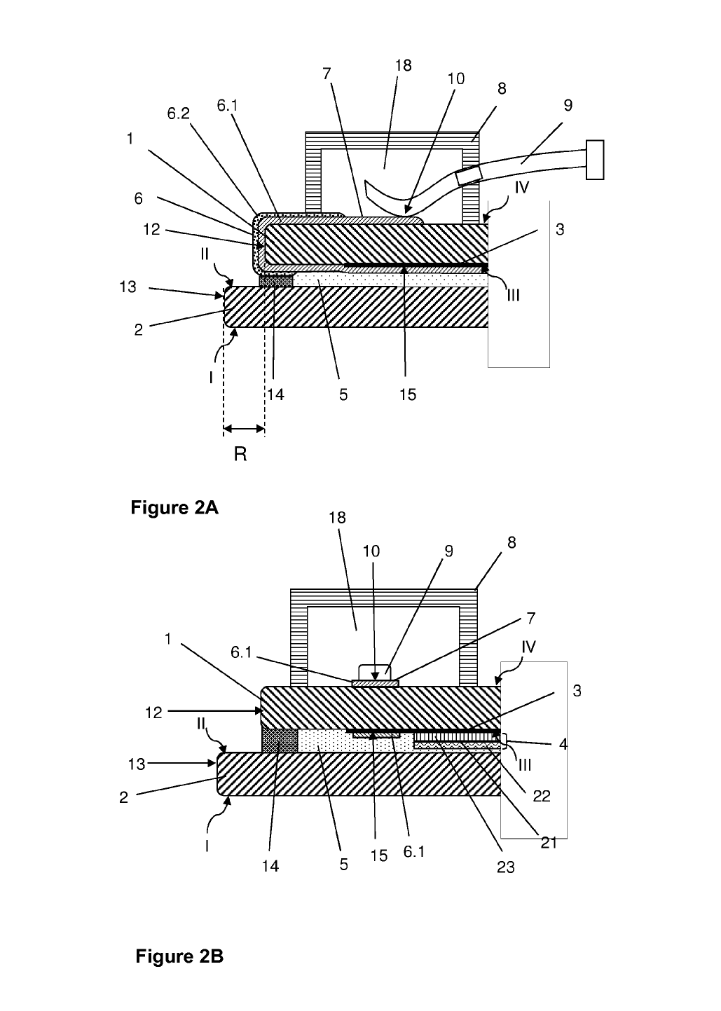

FIG. 2 a schematic representation of a solar module according to the invention in a view of the back side of the substrate,

FIG. 2A a cross-sectional drawing along the line A-A′ of FIG. 2,

FIG. 2B a cross-sectional drawing along the line B-B′ of FIG. 2,

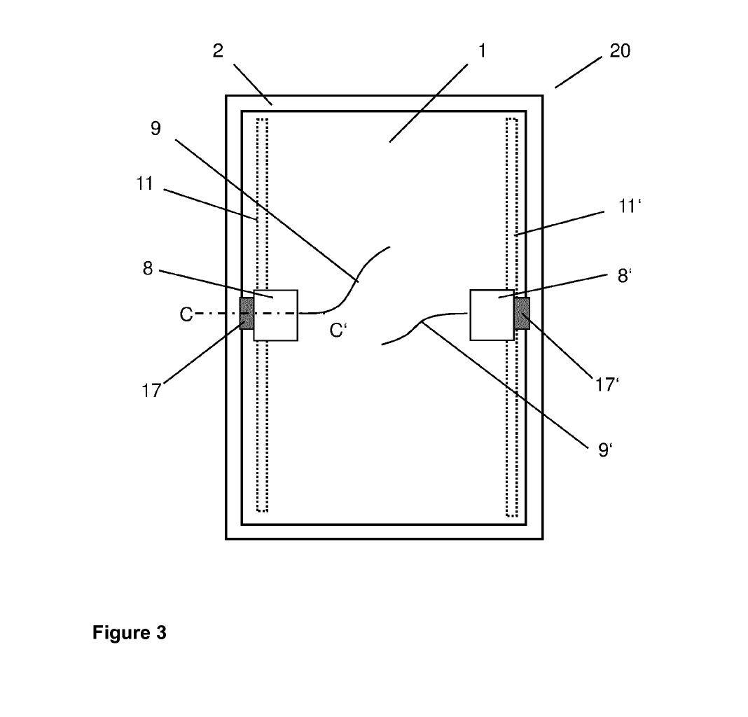

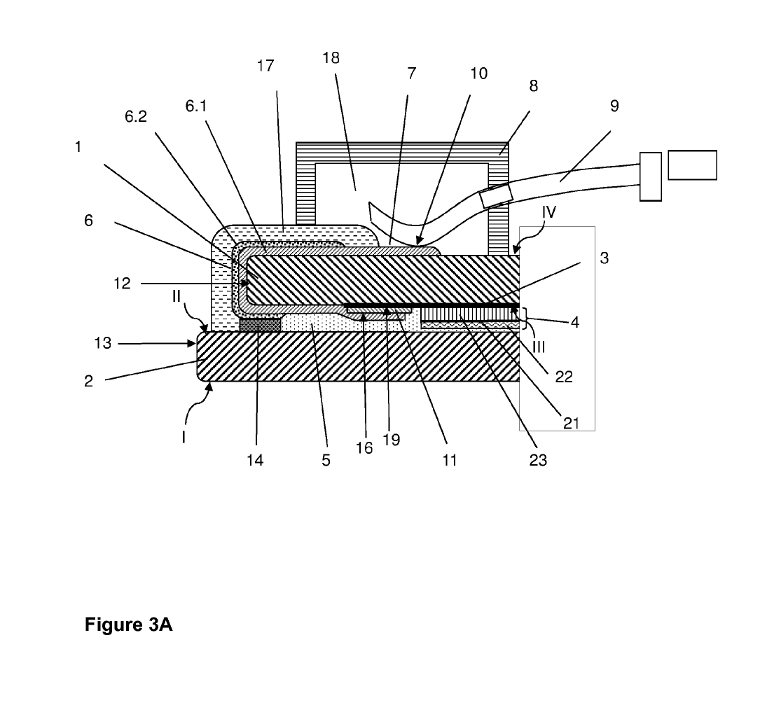

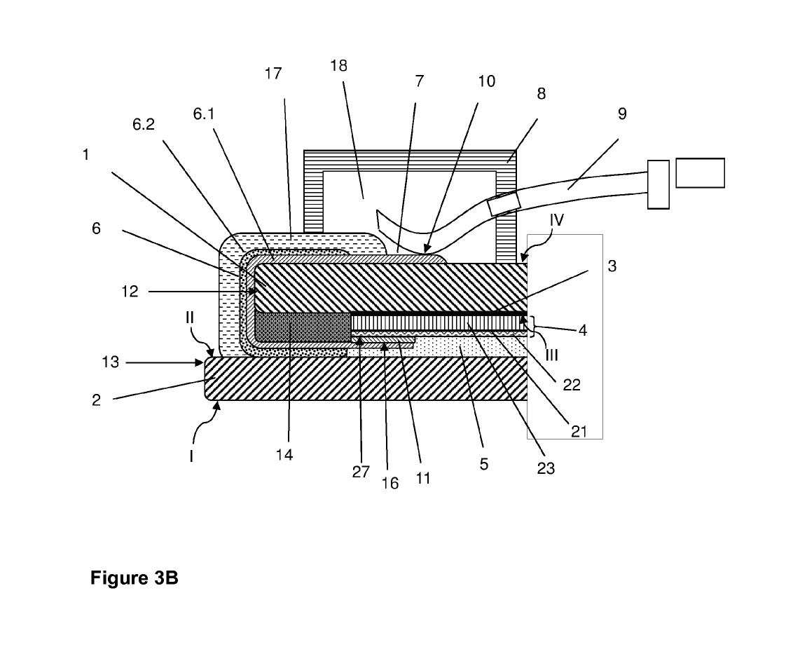

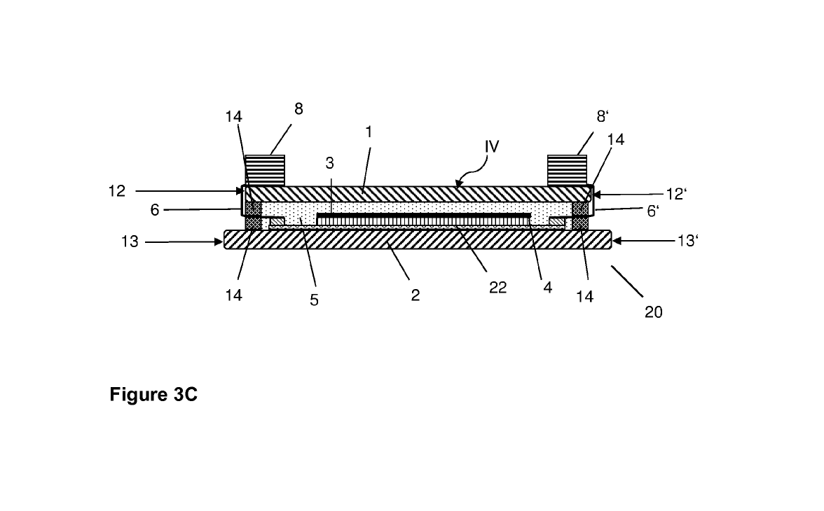

FIG. 3 a schematic representation of another embodiment of the solar module according to the invention in a view of the back side of the substrate,

FIG. 3A a cross-sectional drawing along the line C-C′ of FIG. 3,

FIG. 3B a cross-sectional drawing along the line C-C′ of FIG. 3 of another embodiment of the thin-film solar module according to the invention,

FIG. 3C a cross-sectional drawing of an improvement of the solar module according to the invention of FIG. 3,

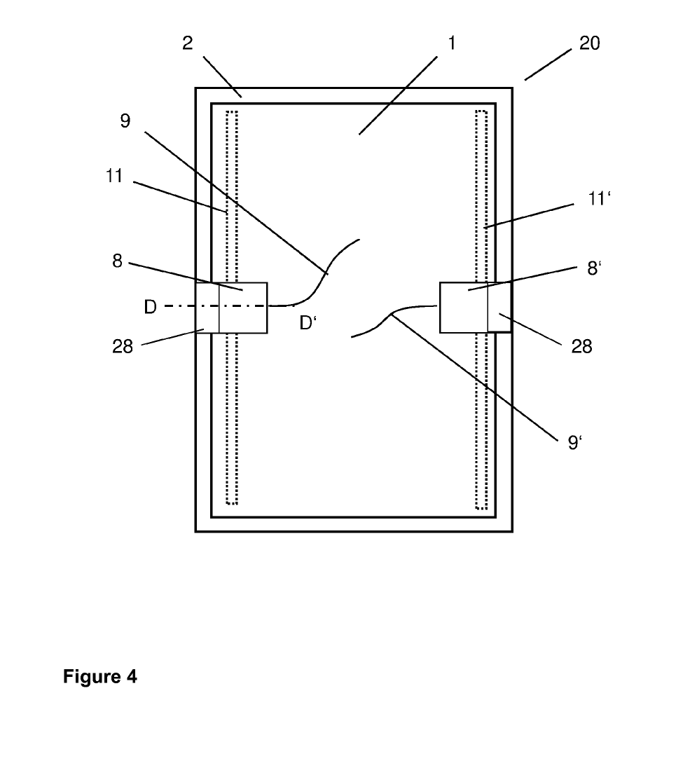

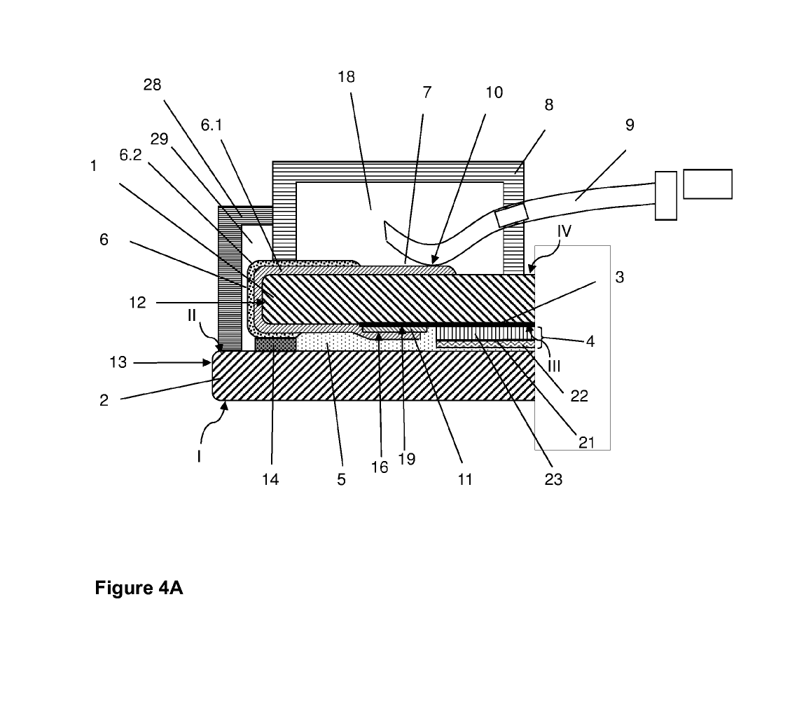

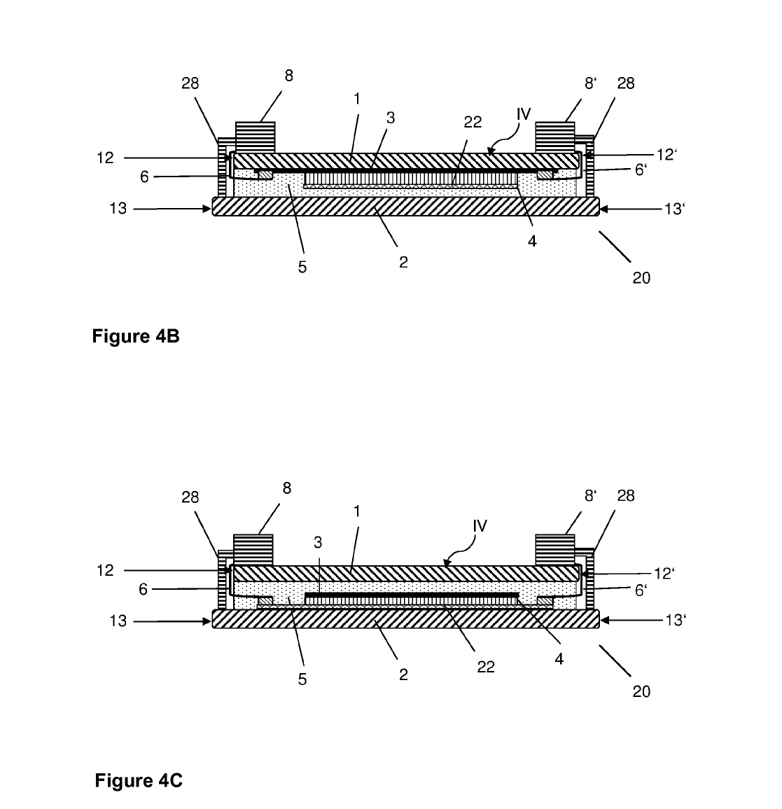

FIG. 4 a schematic representation of another embodiment of the solar module according to the invention in a view of the back side of the substrate,

FIG. 4A a cross-sectional drawing along the line D-D′ of FIG. 4,

FIG. 4B a cross-sectional drawing of an improvement of the solar module according to the invention in substrate configuration,

FIG. 4C a cross-sectional drawing of an improvement of the solar module according to the invention in superstrate configuration,

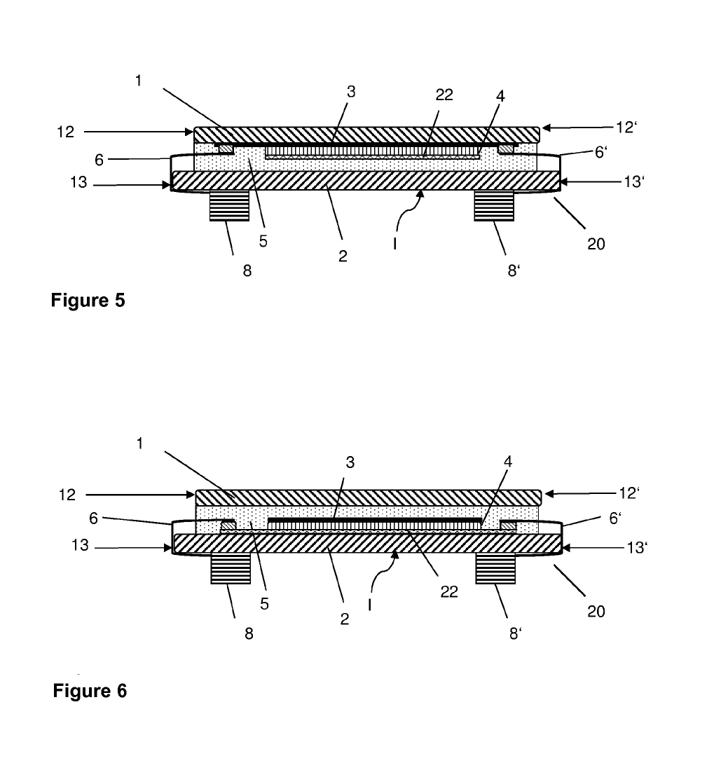

FIG. 5 a cross-sectional drawing of an improvement of the solar module according to the invention in substrate configuration,

FIG. 6 a cross-sectional drawing of an improvement of the solar module according to the invention in superstrate configuration,

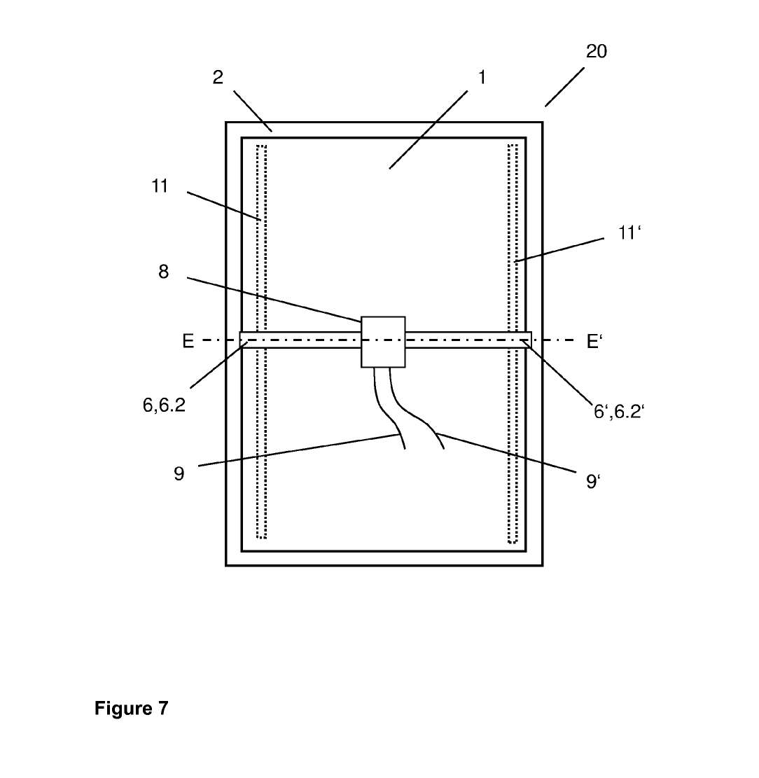

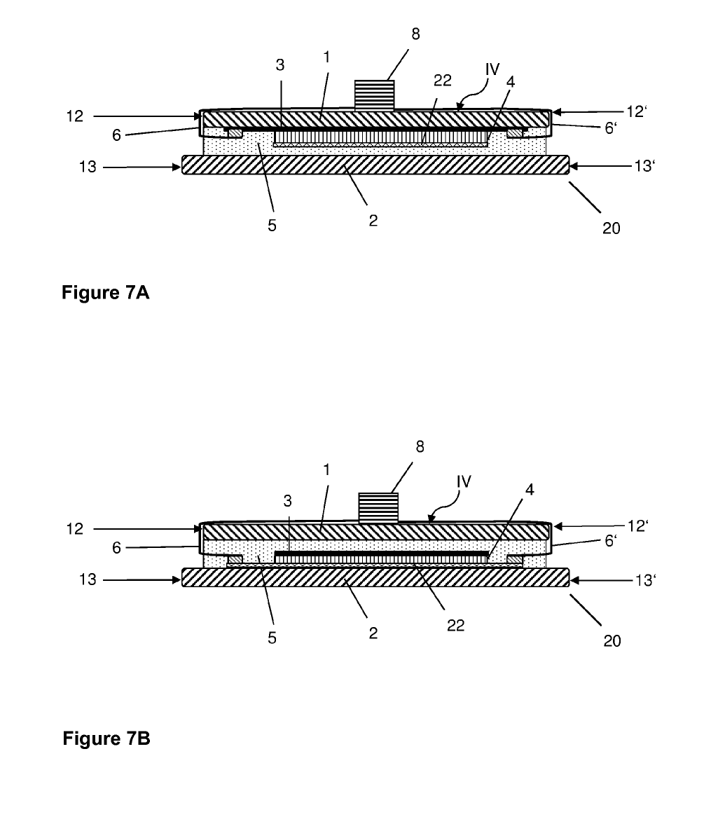

FIG. 7 a schematic representation of another embodiment of the solar module according to the invention in a view of the back side of the substrate,

FIG. 7A a cross-sectional drawing along the line E-E′ of FIG. 7 of an improvement of the solar module according to the invention in substrate configuration,

FIG. 7B a cross-sectional drawing along the line E-E′ of FIG. 7 of an improvement of the solar module according to the invention in superstrate configuration,

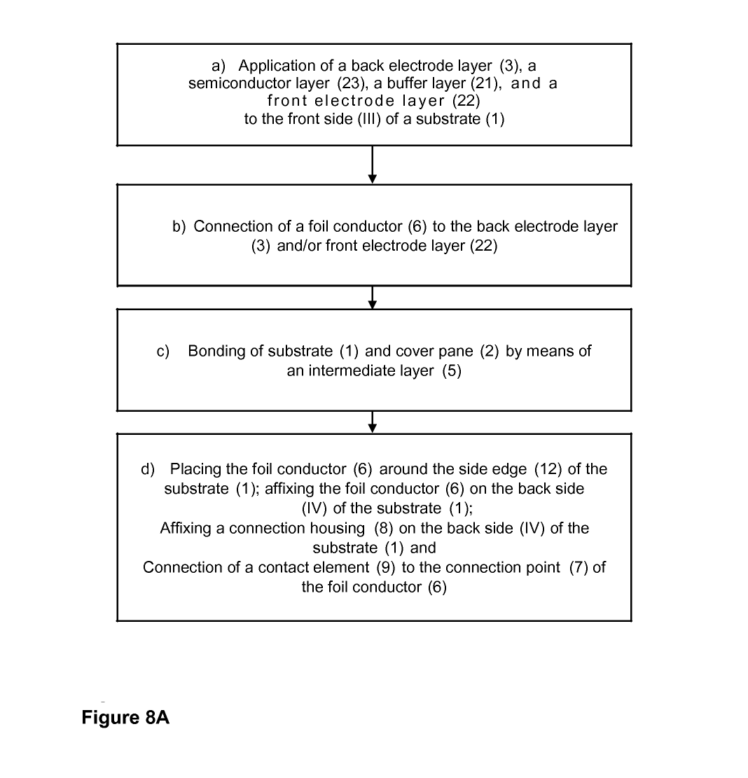

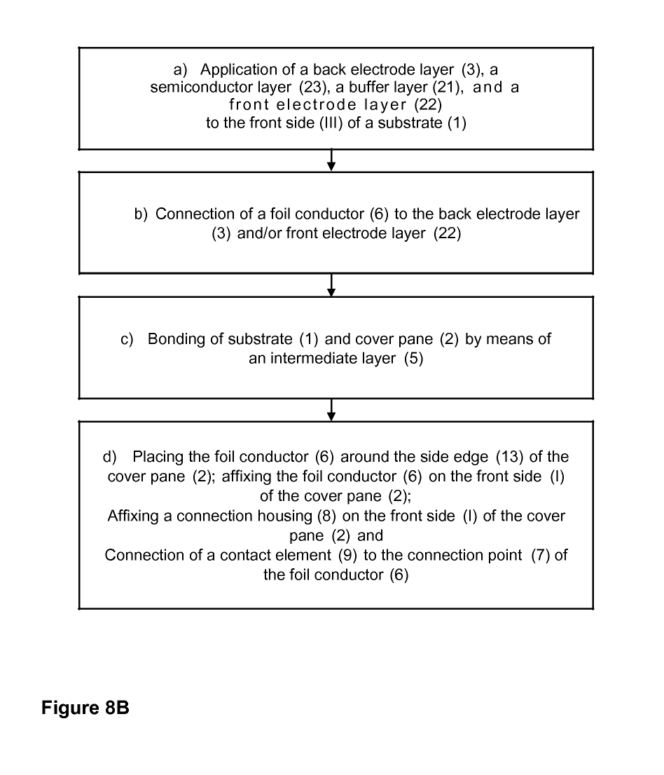

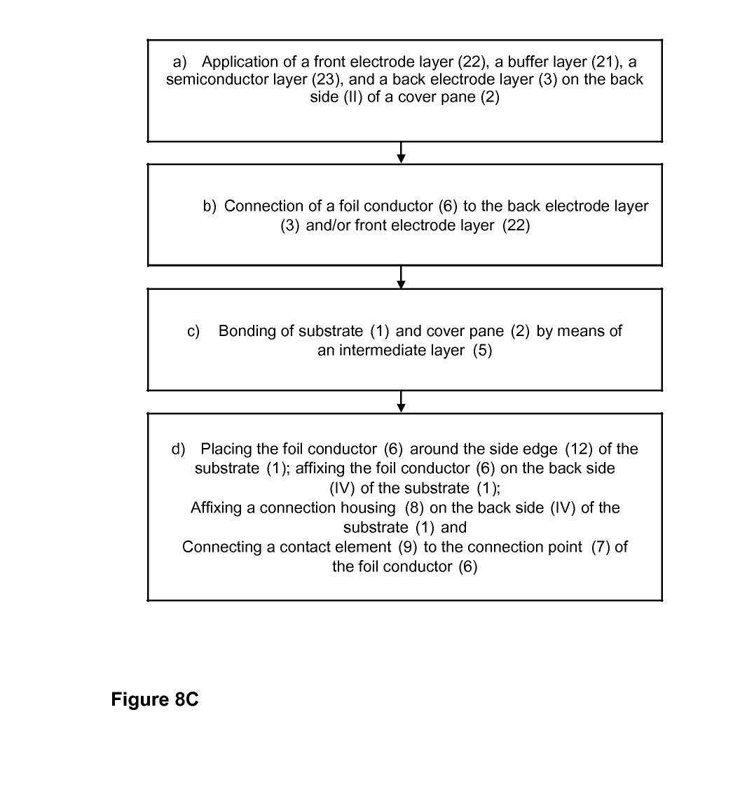

FIG. 8A an exemplary embodiment of the steps of the method according to the invention by means of a flowchart,

FIG. 8B another exemplary embodiment of the steps of the method according to the invention by means of a flowchart,

FIG. 8C another exemplary embodiment of the steps of the method according to the invention by means of a flowchart,

FIG. 8D another exemplary embodiment of the steps of the method according to the invention by means of a flowchart, and

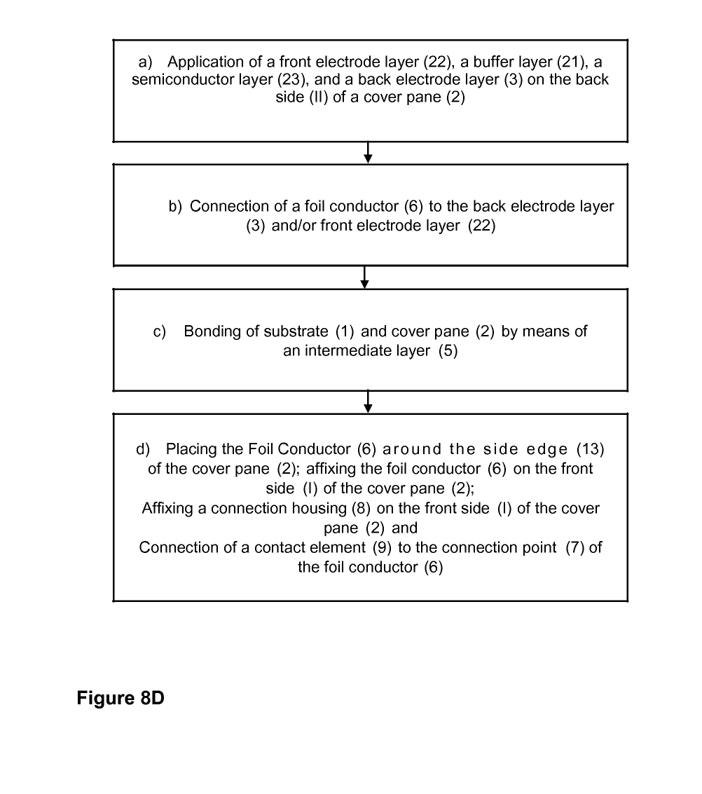

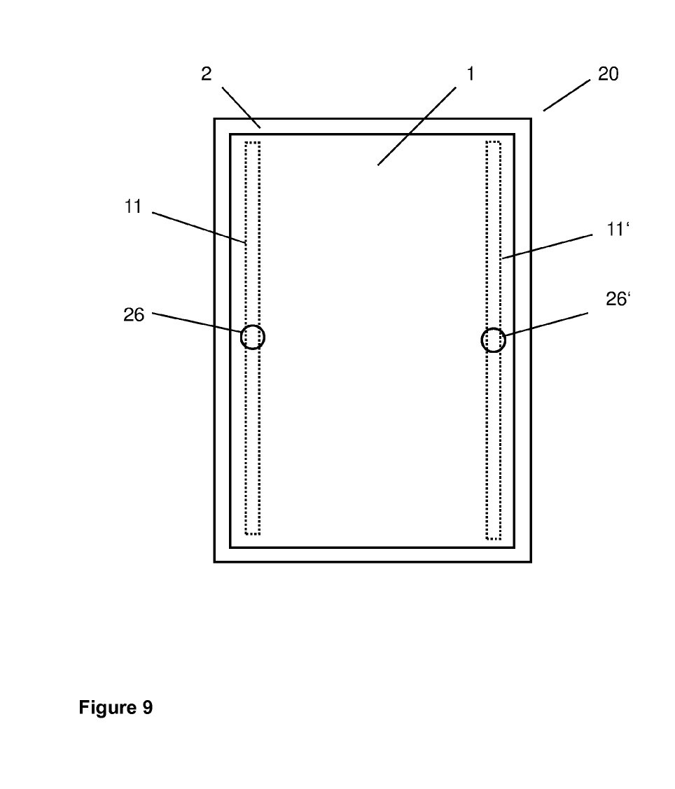

FIG. 9 a solar module according to the prior art in a view of the back side of the substrate.

The following figures depict an embodiment of a solar module according to the invention with a connection element, using the example of a thin-film solar module (20).

FIG. 1 depicts two solar cells (20.1) and (20.2) of a thin-film solar module (20) in substrate configuration. The thin-film solar module (20) comprises an electrically insulating substrate (1) with a layer structure applied thereon to form a photovoltaically active absorber layer (4). The layer structure is disposed on the light-entry front side (III) of the substrate (1). In this case, the substrate (1) is made, for example, of glass with relatively low light transmittance, with it equally possible to use other insulating materials with sufficient strength as well as inert behavior relative to the process steps performed.

The layer structure comprises a back electrode layer (3) disposed on the front side (III) of the substrate (1). The back electrode layer (3) contains, for example, a layer of an opaque metal such as molybdenum and is, for example, applied by cathode sputtering on the substrate (1). The back electrode layer (3) has, for example, a layer thickness of roughly 1 μm. In another embodiment, the back electrode layer (3) includes a layer stack of different individual layers. Preferably, the layer stack contains a diffusion barrier to prevent diffusion of, for example, sodium out of the substrate (1) into the photovoltaically active absorber layer (4).

A photovoltaically active absorber layer (4), whose band gap is preferably capable of absorbing the greatest possible share of sunlight, is deposited on the back electrode layer (3). The photovoltaically active absorber layer (4) contains a p-doped semiconductor layer (23), for example, a p-conductive chalcopyrite semiconductor, such as a compound of the group copper indium diselenide (CuInSe₂), in particular sodium (Na)-doped Cu(InGa)(SSe)₂. The semiconductor layer (23) has, for example, a layer thickness of 500 nm to 5 μm and, in particular, roughly 2 μm. A buffer layer (21), which includes here, for example, a single layer of cadmium sulfide (CdS) and a single layer of intrinsic zinc oxide (i-ZnO), is deposited on the semiconductor layer (23). A front electrode layer (22) is applied, for example, by vapor deposition, on the buffer layer (21). The front electrode layer (22) (“window layer”) is transparent to radiation in the spectral range susceptible to the semiconductor layer (23), to ensure only a slight reduction of the incident sunlight. The transparent front electrode layer (22) can, by way of generalization, be referred to as a TCO-layer (TCO=transparent conductive electrode) and is based on a doped metal oxide, for example, n-conductive, aluminum-doped zinc oxide (AZO). A pn-heterojunction, i.e., a sequence of different layers of the opposing conductor type, is formed by the front electrode layer (22), the buffer layer (21), and the semiconductor layer (23). The layer thickness of the front electrode layer (22) is, for example, 300 nm.

The layer system is divided, in a method known per se for producing a thin-film solar module, into individual photovoltaically active regions, so-called solar cells (20.1) and (20.2). The division is accomplished by incisions (24.1), (24.2), and (24.3) using a suitable structuring technology, such as laser writing and mechanical processing, for example, by drossing or scratching. The individual solar cells (20.1) and (20.2) are serially connected to each other via a region (25) of the back electrode layer (3).

A thin-film solar module (20) according to the invention has, for example, 100 serially connected solar cells and an open circuit voltage of 56 volt. In the example depicted here, both the resultant positive (+) and the resultant negative (−) power connection of the thin-film solar module (20) are guided over the back electrode layer (3) and electrical contact is made there.

For protection against environmental influences, an intermediate layer (5), which contains, for example, polyvinyl butyral (PVB) or ethylene vinyl acetate (EVA), is applied on the front electrode layer (22). The thickness of the intermediate layer (5) is, for example, 0.76 mm. In addition, the layer structure consisting of the substrate (1), back electrode layer (3), and photovoltaically active absorber layer (4) are sealed via the intermediate layer (5) with a cover pane (2). The cover pane (2) is transparent to sunlight and contains, for example, tempered, extra white glass with a low iron content. The cover pane (2) has, for example, an area of 1.6 m×0.7 m. The entire thin-film solar module (20) is affixed for installation at the use site in an aluminum hollow-chamber frame which is not shown here.

FIG. 2 depicts a schematic view of a thin-film solar module (20) according to the invention; FIG. 2A, a sectional drawing along the line A-A′ of FIG. 2; and FIG. 2B, a sectional drawing along the line B-B′ of FIG. 2. Since the back electrode layer (3) is susceptible to oxidation and corrosion, it is not usually guided to the outer side edge (12) of the substrate (1). The region without back electrode layer (3) preferably has a width of 10 mm to 20 mm, for example, 15 mm, relative to the outer side edge (12) of the substrate (1). In the production process, the back electrode layer (3) is usually deposited over the entire substrate (1). The decoating of the edge region then takes place in a second step, for example, by means of laser ablation, plasma etching, or mechanical methods. Alternatively, masking techniques can be used.

A circumferential edge region of the back electrode layer (3) with a width of, for example, 15 mm is not coated with the photovoltaically active absorber layer (4). In this region, the back electrode layer (3) can be electrically conductively connected to the electrically conductive layer (6.1) of a foil conductor (6). The electrical line connection (15) is made, for example, by welding, bonding, soldering, or gluing, with an electrically conductive adhesive. The electrically conductive layer (6.1) of the foil conductor (6) contains, for example, an aluminum strip (6.1) with a thickness of, for example, 0.1 mm and a width of, for example, 20 mm. The electrical line connection (15) is made with an aluminum strip preferably by ultrasonic bonding. The electrically conductive layer (6.1) of the foil conductor (6) is completely covered, for example, on one side, in particular on both sides, with an electrically insulating foil (6.2) made, for example, of polyimide. The foil conductor (6) is already prefabricated, i.e., the electrically insulating foil (6.2) is already fixedly bonded to the electrically conductive layer (6.1) before application of the foil conductor (6) on the solar module (20). Advantageously, the electrically conductive layer (6.1) is laminated with an electrically insulating foil (6.2) on one side or with two electrically insulating foils (6.2) on both sides.

The electrically insulating foil (6.2) is disposed on the outer side of the electrically conductive layer (6.1) of the foil conductor (6), in other words, on the side of the electrically conductive layer (6.1) facing away from the substrate (1). The electrically insulating foil (6.2) has, for example, a thickness of 0.02 mm and a width of 25 mm. The foil conductor (6) is preferably also glued to the surface of the substrate (1). In an alternative embodiment, the electrically conductive layer (6.1) of the foil conductor (6) includes a tinned copper strip. In another alternative embodiment, the electrically conductive layer (6.1) of the foil conductor (6) is completely covered on both sides with an electrically insulating foil (6.2).

The foil conductor (6) has a connection point (7) for making electrical contact. At the connection point (7), the electrically insulating foil (6.2) is removed and the electrically conductive layer (6.1) is freely accessible. In the example depicted, the connection point (7) is disposed on the back side (IV) of the substrate (1) at a distance of roughly 20 mm from the side edge (12). The connection point (7) can be disposed at any point on the back side (IV) of the substrate (1) or on its side edge (12).

In FIG. 2A and 2B, the substrate (1) is undercut or set back compared to the cover pane (2) by a distance R of, for example, 5 mm. The foil conductor (6) runs in the space thus created. The foil conductor (6) does not protrude at its exit point from the composite of substrate (1) and cover pane (2) beyond the cover pane (2) and is protected against external mechanical stresses.

In the example shown, the electrical line connection (10) to the connection point (7) of the foil conductor (6) is made via a spring contact element (9). For a foil conductor (6) with an electrically conductive layer (6.1) made of aluminum, it is expedient to plate the electrically conductive layer (6.1) with tin in the region of the connection point (7). The spring contact element (9) is, for example, connected to blocking diodes or to an external electrical control system. The spring contact element (9) enables making contact easily and quickly without additional steps such as soldering or gluing.

In this exemplary embodiment, the positive and the negative power connection of the thin-film solar module (20) are electrically contacted via two foil conductors (6) and (6′) and two connection housings (8) and (8′).

The connection housings (8) and (8′) are configured with their spring contact elements (9) and (9′) such that they can be easily, quickly, and automatically assembled. In FIG. 2A and FIG. 2B, the connection housing (8) is, for example, glued to the substrate (1).

The gluing of the connection housing (8) to the substrate (1) can, for example, be done with an acrylate adhesive or a polyurethane adhesive. In addition to the simple and long-lasting bonding between the connection housing (8) and substrate (1), these adhesives have a sealing function and protect the electrical line connection (10) between the foil conductor (6) and contact element (9) against moisture and corrosion. By means of the sealing of the voltage-carrying electrical conductors, a necessary electrical protection class of the electrical connection can also be obtained. This is, for example, essential for use outdoors. In a preferred embodiment, the interior of the connection housing is at least partially filled with a sealing means (18), for example, with polyisobutylene. The electrically insulating sealing means (18) increases the dielectric strength and reduces penetrating moisture and leakage currents associated therewith.

The electrically conductive layer (6.1) of the foil conductor (6) need not be bare metal at the connection point (7), but can be coated with a protective layer of paint or a plastic foil. This protective layer protects the metal contact surface against oxidation and corrosion during the production process. The protective layer can be penetrated by an object for making contact, for example, by a contact pin or a contact needle. Alternatively, the protective layer can be made from a plastic foil that is glued on and is removable. The plastic foil can already be applied during production of the foil conductor (6) and then removed during assembly before the actual electrical contact with the contact element (9) is made. The connection point (7) of the foil conductor (6) can, for example, be pre-tinned.

The gap between substrate (1) and cover pane (2) is circumferentially sealed with an edge seal (14) as a vapor diffusion barrier, preferably with a plastic material, for example, polyisobutylene. The hermetic sealing of the edge gap protects the corrosion-sensitive photovoltaically active absorber layer (4) against atmospheric oxygen and moisture.

FIG. 3 depicts another embodiment of the thin-film solar module according to the invention (20) in a view of the back side (IV) of the substrate (1).

FIG. 3A is a cross-sectional drawing along the line C-C′ of FIG. 3. A bus bar (11) is connected via an electrical line connection (19) to the back electrode layer (3). The bus bar (11) contains, for example, an aluminum strip with a width of 3 mm to 5 mm and a thickness of 0.1 mm to 0.2 mm. The bus bar (11) is disposed in its long direction along the long side of the thin-film solar module (20). The electrical line connection (19) between the bus bar (11) and the back electrode layer (3) is made using bus bars (11) made of aluminum, preferably by ultrasonic bonding. The electrically conductive layer (6.1) of the foil conductor (6) is connected to the bus bar (11) via an electrical line connection (16). The foil conductor (6) is guided out of the composite of substrate (1), intermediate layer (5), and cover pane (2) and around the edge (12) of the substrate (1). The electrically conductive layer (6.1) of the foil conductor (6) contains, for example, an aluminum strip with a width of 20 mm and a thickness of 0.1 mm. The electrically insulating foil (6.2) of the foil conductor (6) contains, for example, a plastic film made of polyimide with a width of 25 mm and a thickness of 0.02 mm. In addition, the foil conductor (6) has, outside the composite, a protective layer (17) different from the plastic foil of the foil conductor (6) and the thermoplastic intermediate layer (5), for example, a layer sequence of polyvinyl fluoride/polyester/polyvinyl fluoride with a total thickness of 0.5 mm. The layer sequence is glued, for example, by means of a layer of ethyl vinyl acetate, to the surface of the substrate (1). The protective layer (17) protects the foil conductor long-term against mechanical damage. The protective layer (17) additionally protects the edge gap between substrate (1) and cover pane (2) at the exit point of the foil conductor (6) against penetrating moisture. For this purpose, the protective layer (17) spans the exit point of the foil conductor (6) between substrate (1) and cover pane (2). Here, the protective layer (17) is fixedly bonded both to the cover pane (2) in its edge protruding beyond the substrate (1) and to the substrate (1). The protective layer (17) extends into the connection housing (8) and, there, is connected thereto, in particular in the region of the connection point (7) of the foil conductor (6).

The invention is by no means restricted to contacting the back electrode layer (3). In an alternative embodiment of the thin-film solar module according to the invention, the resultant positive and the resultant negative power connection of the thin-film solar module is guided over the front electrode layer (22) and electrical contact is made there. Alternatively, one power connection can be made via the back electrode layer (3); and the second power connection, via the front electrode layer (22).

FIG. 3B depicts a cross-sectional drawing along the line C-C′ of FIG. 3 of another embodiment of the thin-film solar module (20) according to the invention. A bus bar (11) is connected via an electrical line connection (27) to the front electrode layer (22). The electrically conductive layer (6.1) of the foil conductor (6) is is connected via an electrical line connection (16) to the bus bar (11). The foil conductor (6) is guided out of the composite of substrate (1), intermediate layer (5), and cover pane (2) and around the edge (12) of the substrate (1). The electrically insulating foil (6.2) of the foil conductor (6) is preferably glued to the cover pane (2). The gluing prevents penetration of moisture into the interior of the thin-film solar module (20) and, thus, the corrosion of the photovoltaically active absorber layer (4).

FIG. 3C depicts another embodiment of the thin-film solar module (20) of FIG. 3, wherein, again, the foil conductor (6) is guided out of the composite of substrate (1), intermediate layer (5), and cover pane (2) and around the edge (12) of the substrate (1). The gap between substrate (1) and cover pane (2) is circumferentially sealed with an edge seal (14) as a vapor diffusion barrier which is situated on both sides of the foil conductor (6). The hermetic sealing of the edge gap for protection of the corrosion sensitive photovoltaically active absorber layer (4) against atmospheric oxygen and moisture can thus be even further improved.

FIG. 4 depicts another embodiment of the thin-film solar module (20) according to the invention in a view of the back side (IV) of the substrate (1). The connection housings (8) and (8′) have, in each case, an additional protective element (28). FIG. 4A depicts a cross-sectional drawing along the line D-D′ of FIG. 4. The additional protective element (28) is disposed in the region of the exit point of the foil conductor (6) from the composite of substrate (1), intermediate layer (5), and cover pane (2). The protective element (28) can be made of the same material as the connection housing (8), for example, of a plastic, and be already integrated at the time of the production of the connection housing (8). Alternatively, the protective element (28) can be an additional component that is connected to the connection housing (8). In this non-restrictive example, the protective element (28) does not protrude beyond the side edge (13) of the cover pane (2). The protective element can additionally be glued to the side edge (12) of the substrate (1) and the back side (II) of the cover pane (2). The cavity (29) between protective element (28) and substrate (1) is preferably filled, for moisture insulation, with a sealing means, for example, with polyisobutylene.

FIG. 4B depicts a cross-sectional drawing of a solar module (20) according to the invention in a simplified representation. The photovoltaically active absorber layer (4) is connected in substrate configuration via the back electrode layer (4) to the substrate (1). The foil conductors (6) and (6′) are disposed around the side edges (12) and (12′) of the substrate (1). Two connection housings (8) and (8′) are disposed on the back side (IV) of the substrate (1). Each connection housing (8) and (8′) has an electrical line connection (not shown here) between the respective foil conductor (6) and (6′) and a contact element. Each connection housing (8) and (8′) has a protective element (28), which protects the foil conductors (6) and (6′) at their exit point from the composite of substrate (1), intermediate layer (5), and cover pane (2).

FIG. 4C depicts a cross-sectional drawing of a solar module (20) according to the invention in a simplified representation. The photovoltaically active absorber layer (4) is connected in superstrate configuration to the cover pane (2). The foil conductors (6) and (6′) are disposed around the side edges (12) and (12′) of the substrate (1). Two connection housings (8) and (8′) are disposed on the back side (IV) of the substrate (1). Each connection housing (8) and (8′) has a protective element (28), which protects the foil conductors (6) and (6′) at their exit point from the composite of substrate (1), intermediate layer (5), and cover pane (2).

FIG. 5 depicts a cross-sectional drawing of a solar module (20) according to the invention in a simplified representation. The photovoltaically active absorber layer (4) is connected in substrate configuration via the back electrode layer (4) to the substrate (1). The foil conductors (6) and (6′) are disposed around the side edges (13) and (13′) of the cover pane (2). Two connection housings (8) and (8′) are disposed on the front side (I) of the cover pane (2).

FIG. 6 depicts a cross-sectional drawing of a solar module according to the invention (20) in a simplified representation. The photovoltaically active absorber layer (4) is connected in superstrate configuration to the cover pane (2). The foil conductors (6) and (6′) are disposed around the side edges (13) and (13′) of the cover pane (2). The foil conductors (6) and (6′) are disposed around the side edges (13) and (13′) of the cover pane (2). Two connection housings (8) and (8′) are disposed on the front side (I) of the cover pane (2).

FIG. 7 depicts another embodiment of the thin-film solar module (20) according to the invention, wherein the two foil conductors (6) and (6′) on the back side (IV) of the substrate (1) are combined into a common connection housing (8). The connection housing (8) is disposed, in this example, in the center of the back side (IV) of the substrate (1). The connection housing (8) can be disposed at any point on the back side (IV) of the substrate (1) or on the side edge (12) of the substrate (1).

In this embodiment, the positive and the negative power connection of the solar module (20) are electrically contacted by two foil conductors (6) and (6′) and one connection housing (8).

FIG. 7A depicts a cross-sectional drawing of a solar module (20) according to the invention in a simplified representation. The photovoltaically active absorber layer (4) is connected in substrate configuration via the back electrode layer (3) to the substrate (1). The foil conductors (6) and (6′) are disposed around the side edges (12) and (12′) of the substrate (1). The connection housing (8) is disposed on the back side (IV) of the substrate (1). The connection housing (8) has two electrical line connections (not shown here) between the respective foil conductor (6) and (6′) and one contact element each.

FIG. 7B depicts a cross-sectional drawing of a solar module (20) according to the invention in a simplified representation. The photovoltaically active absorber layer (4) is connected in superstrate configuration to the cover pane (2). The foil conductors (6) and (6′) are disposed around the side edges (12) and (12′) of the substrate (1). The connection housing (8) is disposed on the back side (IV) of the substrate (1). The connection housing (8) has two electrical line connections (not shown here) between the respective foil conductor (6) and (6′) and one contact element each.

FIG. 8A depicts a flowchart of the steps of the method according to the invention for producing a thin-film solar module (20) with substrate configuration and arrangement of the connection housing (8) on the back side (IV) of the substrate (1).

FIG. 8B depicts a flowchart of the steps of the method according to the invention for producing a thin-film solar module (20) with substrate configuration and arrangement of the connection housing (8) on the front side (I) of the cover pane (2).

FIG. 8C depicts a flowchart of the steps of the method according to the invention for producing a thin-film solar module (20) with superstrate configuration and arrangement of the connection housing (8) on the back side (IV) of the substrate (1).

FIG. 8D depicts a flowchart of the steps of the method according to the invention for producing a thin-film solar module (20) with superstrate configuration and arrangement of the connection housing (8) on the front side (I) of the cover pane (2).

FIG. 9 depicts a thin-film solar module (20) according to the prior art in a view of the back side (IV) of the substrate (1). The substrate (1) has two through-holes (26) and (26′), which are disposed above the bus bars (11) and (11′). Electrical contact of the bus bars (11) and (11′) is made through the through-holes holes (26) and (26′), for example, by a contact element which is not shown here. The through-holes (26) and (26′) reduce the mechanical stability of the substrate (1).

The thin-film solar module (20) according to the invention has some advantages compared to the thin-film solar modules according to the prior art: At the time of introduction of the through-holes (26) and (26′) in glass substrates (1) of thin-film solar modules according to the prior art, in approx. 3% of the substrates (1) breakage or spalling occurs such that the substrates (1) have to be discarded. This process step is omitted in the case of thin-film solar modules (20) according to the invention.

Moreover, in an experiment, 100 thin-film solar modules (20) were loaded with a simulated maximum snow load of 5400 Pa corresponding to the standard IEC61646, 2nd edition. In 5% of the thin-film solar modules (20) with through-holes (26) and (26′) according to the prior art, substrate breakage occurred. Here, the break lines began in the region around the through-holes and spread out from there. With thin-film solar modules (20) according to the invention, under the same load conditions, substrate breakage occurred in no case.

This result was unexpected and surprising for the person skilled in the art.

### LIST OF REFERENCE SIGNS

(1) substrate

(2) cover pane

(3) back electrode layer

(4) photovoltaically active absorber layer

(5) intermediate layer, thermoplastic intermediate layer

(6), (6′) foil conductor

(6.1), (6.1′) electrically conductive layer of (6)

(6.2), (6,2′) electrically insulating foil of (6)

(7) connection point

(8), (8′) connection housing

(9), (9′) contact element, spring contact element, feed line

(10) electrical line connection between (6) and (9)

(11), (11′) bus bar

(12), (12′) side edge of (1)

(13), (13′) side edge of (2)

(14) edge seal

(15) electrical line connection between (6) and (3)

(16) electrical line connection between (6) and (11)

(17), (17′) protective layer of (6)

(18) sealant

(19) electrical line connection between (11) and (3)

(20) solar module, thin-film solar module

(20.1), (20.2) solar cell

(21) buffer layer

(22) front electrode layer

(23) semiconductor layer

(24.1), (24.2), (24.3) division

(25) region of (3)

(26), (26′) through-hole

(27) electrical line connection between (11) and (22)

(28) protective element

(29) cavity

I front side of (2)

II back side of (2)

III front side of (1)

IV back side of (1)

A-A′ section line

B-B′ section line

C-C′ section line

D-D′ section line

E-E′ section line

R undercut

1. A solar module with a connection element, comprising:
a substrate, a back electrode layer, a photovoltaically active absorber layer, and a cover pane,
wherein the photovoltaically active absorber layer is partially connected electrically and conductively to the back electrode layer and has, on a side turned away from the back electrode layer, a front electrode layer, and the substrate is laminarly connected on a front side by means of at least one intermediate layer to a back side of the cover pane,
at least one prefabricated foil conductor that comprises at least one electrically conductive layer and one electrically insulating foil and that is electrically and conductively connected to the back electrode layer and/or front electrode layer and has a connection point for making electrical contact, and
at least one connection housing that has at least one electrical line connection between a contact element and the connection point of the at least one prefabricated foil conductor,
wherein
the at least one prefabricated foil conductor is disposed around a side edge of the substrate, and the at least one prefabricated foil and the at least one connection housing are affixed on a back side of the substrate, or
the at least one prefabricated foil conductor is disposed around a side edge of the cover pane, and the at least one prefabricated foil conductor and the at least one connection housing are affixed on a front side of the cover pane.

2. The solar module according to claim 1, wherein the substrate has the back electrode layer on the front side.

3. The solar module according to claim 1, wherein the cover pane has the photovoltaically active absorber layer on the back side of the cover pane.

4. The solar module according to claim 1, wherein the at least one prefabricated foil conductor is connected via a bus bar to the back electrode layer and/or front electrode layer.

5. The solar module according to claim 1, wherein the at least one prefabricated foil conductor and/or the bus bar contains a metal, preferably aluminum, silver, or copper.

6. The solar module according to claim 1, wherein the back electrode layer contains a metal, preferably molybdenum, titanium nitride compounds, or tantalum nitride compounds, and the front electrode layer preferably contains an n-conductive semiconductor, preferably aluminum-doped zinc oxide or indium-tin oxide.

7. The solar module according to claim 1, wherein the photovoltaically active absorber layer contains amorphous, micrmorphous, or polycrystalline silicon, cadmium telluride, gallium arsenide, or copper-indium (Gallium)-sulfur/selenium.

8. The solar module according to claim 1, wherein the substrate and/or the cover pane contains glass, preferably with a thickness of 1.5 mm to 10 mm, and/or the at least one intermediate layer contains a thermoplastic material, preferably polyvinyl butyral or ethylene vinyl acetate with a thickness of 0.3 mm to 0.9 mm.

9. The solar module according to claim 1, wherein the substrate has, relative to the cover pane, an undercut of 0.1 mm to 20 cm, preferably of 1 mm to 10 mm, and the at least one prefabricated foil conductor runs without an overhang around a side edge of the undercut substrate.

10. The solar module according to claim 1, wherein a gap between the substrate and the cover pane is sealed by an edge seal, preferably an adhesive on an acrylic, polyurethane, or polyisobutylene basis.

11. The solar module according to claim 1, wherein the at least one prefabricated foil conductor has, outside a composite of the substrate, the at least one intermediate layer, and the cover pane, at least partially a protective layer, which preferably contains polyacrylic, polyurethane, polyisobutylene, polyimide, polyester, polyethylene, polytetrafluoroethylene, polyvinyl fluoride, polyvinyl butyral, polyethylene naphthalate, ethylene vinyl acetate, silicone, or combinations thereof.

12. The solar module according to claim 1, wherein an interior of the at least one connection housing is sealed by a sealing means, preferably an adhesive on an acrylic, polyurethane, or polyisobutylene basis.

13. The solar module according to claim 1, wherein electrical line connections have soldered, welded, bonded, clamped, or adhesive connections.

14. The solar module according to claim 1, wherein at least two prefabricated foil conductors on the back side of the substrate are electrically and conductively connected in the at least one connection housing to at least two contact elements.

15. A method for producing the solar module with the connection element according claim 1, comprising:
applying the back electrode layer on the front side of the substrate, and applying a semiconductor layer, a buffer layer, and the front electrode layer on the back electrode layer,
connecting, electrically and conductively, the at least one electrically conductive layer of the at least one prefabricated foil conductor to the back electrode layer and/or front electrode layer,
bonding the substrate and the cover pane by means of the at least one intermediate layer under an action of heat, vacuum, and/or pressure, and
placing the at least one prefabricated foil conductor around the side edge of the substrate and affixing the at least one prefabricated foil conductor on the back side of the substrate, the at least one connection housing with at least one contact element being affixed on the back side of the substrate, and the contact element being electrically and conductively connected to the connection point of the at least one prefabricated foil conductor, or
placing the at least one prefabricated foil conductor around the side edge of the cover pane and affixing the at least one prefabricated foil conductor on a front side of the cover pane, the at least one connection housing with at least one contact element being affixed on the front side of the cover pane, and the contact element being electrically and conductively connected to the connection point of the at least one prefabricated foil conductor.

16. A method for producing the solar module with the connection element according to claim 1, comprising:
applying a front electrode layer on the back side of the cover pane, and applying, subsequently, a buffer layer, a semiconductor layer, and the back electrode layer on the front electrode layer,
connecting, electrically and conductively, the at least one electrically conductive layer of the at least one prefabricated foil conductor to the back electrode layer and/or front electrode layer,
bonding the substrate and the cover pane by means of the at least one intermediate layer under an action of heat, vacuum, and/or pressure,
placing the at least one prefabricated foil conductor around the side edge of the substrate and affixing the at least one prefabricated foil conductor on the back side of the substrate, the at least one connection housing with at least one contact element being affixed on the back side of the substrate, and the contact element being electrically and conductively connected to the connection point of the at least one prefabricated foil conductor, or
placing the at least one prefabricated foil conductor around the side edge of the cover pane and affixing the at least one prefabricated foil conductor the front side of the cover pane, the at least one connection housing with at least one contact element being affixed on the front side of the cover pane, and the contact element is being electrically and conductively connected to the connection point of the at least one prefabricated foil conductor.

17. The method for producing the solar module with the connection element according to claim 15, wherein a bus bar is electrically and conductively connected to the back electrode layer and/or front electrode layer; and the at least one prefabricated foil conductor is electrically and conductively connected to the bus bar.

18. A method comprising:
using the connection element according to claim 1 in solar modules, preferably in thin-film solar modules.
